(19) United States
(12) Patent Application Publication
(10) Pub. No.: US 2016/0218671 A1
(43) Pub. Date: Jul. 28, 2016

(54) Fault Detection And Self-Recovery Method For Crystal Oscillator

(71) Applicant: Texas Instruments Incorporated, Dallas, TX (US)

(72) Inventors: Zhang Jun, Shanghai (CN); Yaohua Pan, Shanghai (CN); Lina Bao, Shanghai (CN); ZHIWEI HE, Shanghai (CN)

(21) Appl. No.: 14/814,738

(22) Filed: Jul. 31, 2015

Related U.S. Application Data
(63) Continuation of application No. PCT/CN2015/071730, filed on Jan. 28, 2015.

(51) Int. Cl. H03B 5/06; H03B 5/36

(52) U.S. Cl. CPC H03B 5/06; H03B 5/362

(57) ABSTRACT

Circuitry for providing an oscillating output signal in connection with an integrated circuit chip. This circuitry includes a crystal, off the chip and oscillator circuitry, on the chip, for electrically coupling with the off-chip crystal and operable to produce the oscillating output signal. The preferred embodiment further includes testing circuitry, on the chip, for evaluating whether the oscillating output signal is operating within an acceptable range, as well as operational recovery circuitry, on the chip, for attempting to restore the oscillating output signal, in response to the testing circuitry evaluating that the oscillating output signal is not operating within an acceptable range.

### CROSS-REFERENCES TO RELATED APPLICATIONS

This is a continuation of co-pending International Application No. PCT/CN2015/071730, with an international filing date of Jan. 28, 2015, which designated the United States and is hereby fully incorporated herein by reference for all purposes.

### STATEMENT REGARDING FEDERALLY SPONSORED RESEARCH OR DEVELOPMENT

Not Applicable.

### BACKGROUND OF THE INVENTION

The preferred embodiments relate to oscillators and more particularly to oscillator fault detection and self-recovery.

Electronic oscillators are well-known devices operable to produce an oscillating output signal for timing and synchronization in numerous electronic circuits, devices, and industries. In many of these applications, various or all of the oscillator components are combined into an integrated circuit. Moreover, the integrated circuit may include various other circuits and functionality, where for example many contemporary processors include an on-chip oscillator for providing a clock signal that is used to operate the processor.

A common type of on-chip oscillator is a crystal oscillator, which has much of its circuitry on an integrated circuit chip, although a few of the components may be external from the chip. By way of further background, FIG. 1 illustrates a diagrammatic view of a prior art oscillator 10 in connection with an integrated circuit 100. Integrated circuit 100 may be of various types such as a processor mentioned above, including an external form factor sometimes referred to as a chip or semiconductor package. The chip has various pins or pads along one or more of its edges, so that electrical signals may be coupled and communicated to and/or from circuitry included within the chip. For relevant purposes of the present discussion, two such pads are labeled, one as PAD EXTAL, which is the oscillator input, and one as PAD XTAL, which is the oscillator output. A first capacitor C₁ is connected between PAD EXTAL and ground (also sometimes referred to as V_{SS}), and a second capacitor C₂ is connected between PAD XTAL and ground. Moreover, an oscillator crystal CR has one lead connected to PAD XTAL and another lead to PAD EXTAL. As known in the art, attributes (e.g., piezoelectrical resonance) of oscillator crystal CR will establish the oscillating frequency for oscillator 10. Lastly, in order to properly bias and create feedback with respect to the external devices of FIG. 1, within integrated circuit 100 are connected Other Oscillator Circuitry shown in FIG. 1 in block form, as further detailed below in connection with FIG. 2.

FIG. 2 illustrates a schematic of oscillator 10 of FIG. 1 which, in addition to re-illustrating the oscillator off-chip components of FIG. 1, further details the Other Oscillator Circuitry within the dotted line box. More specifically, such circuitry includes a transistor T₁, illustrated by example as an n-channel transistor, connected generally in a feedback fashion. More particularly, the source of transistor T₁ is connected to ground, and a resistor R₁ is connected between the drain of transistor T₁ and the gate of transistor T₁. The drain of transistor T₁ is also connected to an adjustable current source ACS that is connected to a voltage supply V_{DD} and provides a current, I_{bias}. The gate of transistor T₁ is further connected to PAD EXTAL, and the drain of transistor T₁ is further connected to PAD XTAL. PAD EXTAL is connected to a first input (e.g., inverting) of a comparator CMP, and PAD XTAL is connected to a second input (e.g., non-inverting) of comparator CMP. The output of comparator CMP provides a digital oscillating clock signal, CLK. Lastly, an amplifier is connected as an automatic level control ALC, with a first input (e.g., inverting) connected to receive a reference signal REF, and a second input (e.g., non-inverting) connected to PAD XTAL. The output of automatic level control ALC provides a feedback control to adjustable current source ACS.

The operation of oscillator 10 is known in the art and, thus, is only briefly discussed here. In general, at start-up, power (i.e., an electric field) is provided by the Other Oscillator Circuitry so as to begin to excite crystal CR. As the signal difference between the oscillator input and output (i.e., PADs EXTAL and EXTAL) crosses a threshold detected by comparator CMP, the output clock CLK will alternate state. At the same time, the PAD XTAL is fed back to PAD EXTAL and the gate of transistor T₁, causing a reverse in polarity and thus toward a sinusoidal operation. As this continues, crystal CR will reach its resonance frequency, and thus the output CLK will stabilize at a corresponding digital output frequency. Lastly, note that automatic level control ALC will control adjustable current source ACS, based on a relative comparison to reference REF, thereby controlling the oscillator output amplitude so as to control both power consumption and potential electromagnetic magnetic interference (EMI) of the oscillator.

While the above oscillator 10 and comparable approaches have proven useful and workable in various implementations, the present inventors recognize that such approaches may have drawbacks. Specifically, in various devices, the oscillator output signal CLK can become inoperable (i.e., the oscillator stops oscillating), including once the device has left the manufacturer and reached a customer. Such result may occur from many different factors. For example, failures may occur on the printed circuit board (PCB) on which the layout of FIG. 1 is implemented, such as a wire open or short, failure of a cold solder joint, high leakage on the XTAL/EXTAL PADs, or crystal failure. As another example, a fault may occur on-chip, such as electrical overstress (EOS) or an on-chip conductor open circuit. Still further, problems may arise among the Other Oscillator Circuitry, such as capacitive load, internal transconductance parameters mismatch, other parameter variations, and susceptibility to environmental factors (e.g., temperature, humidity).

Given the preceding, the present inventors have identified potential improvements to the prior art, as are further detailed below.

### BRIEF SUMMARY OF THE INVENTION

In a preferred embodiment, there is circuitry for providing an oscillating output signal in connection with an integrated circuit chip. This circuitry includes a crystal, off the chip and oscillator circuitry, on the chip, for electrically coupling with the off-chip crystal and operable to produce the oscillating output signal. The preferred embodiment further includes testing circuitry, on the chip, for evaluating whether the oscillating output signal is operating within an acceptable range, as well as operational recovery circuitry, on the chip, for attempting to restore the oscillating output signal, in response to the testing circuitry evaluating that the oscillating output signal is not operating within an acceptable range.

Numerous other inventive aspects and preferred embodiments are also disclosed and claimed.

### BRIEF DESCRIPTION OF THE SEVERAL VIEWS OF THE DRAWING

FIG. 1 illustrates a diagrammatic view of a prior art oscillator in connection with an integrated circuit.

FIG. 2 illustrates a schematic of the prior art oscillator of FIG. 1.

FIG. 3 illustrates a diagrammatic view of a preferred embodiment oscillator in connection with an integrated circuit.

FIG. 4 illustrates a combined block diagram and schematic of oscillator FIG. 3.

FIG. 5 illustrates a flowchart of a preferred embodiment method of operation of aspects of the preferred embodiment oscillator.

FIGS. 6a and 6b illustrate voltage waveforms on an oscillator pad representing, respectively, a detected open circuit or closed circuit as between the pad and a respective capacitor.

### DETAILED DESCRIPTION OF EMBODIMENTS

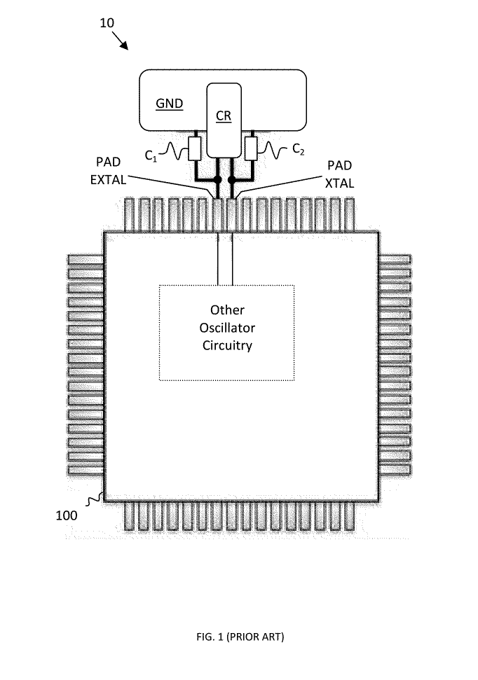

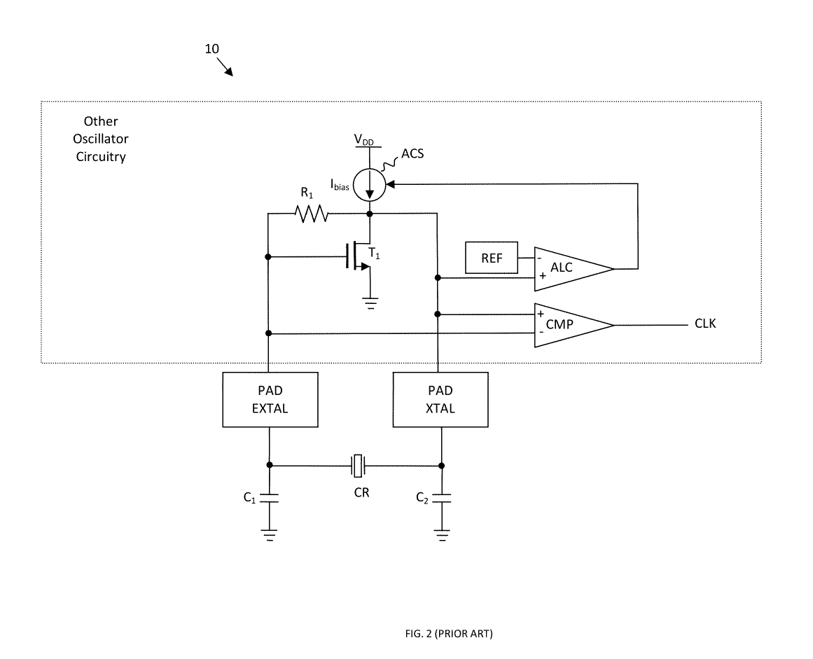

FIGS. 1 and 2 were discussed above in the Background Of The Invention section of this document, and the reader is assumed to be familiar with that discussion.

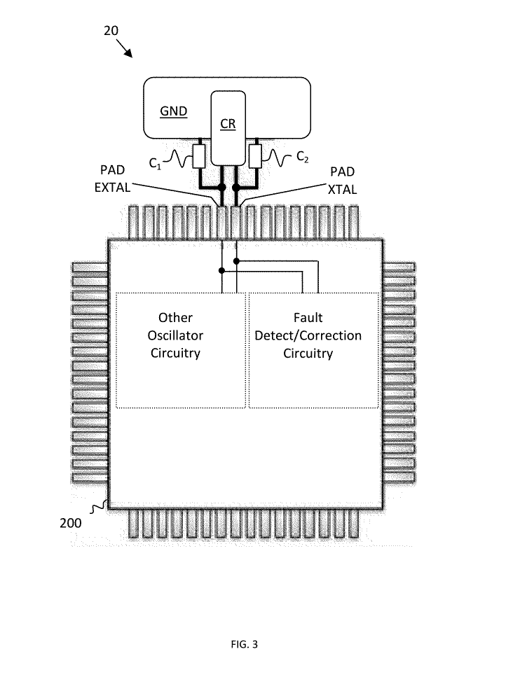

FIG. 3 illustrates a diagrammatic view of an oscillator 20 in connection with an integrated circuit 200, comparable to oscillator 10 and integrated circuit 100 discussed above, but with additional improvements as now described. Specifically, integrated circuit 200 further includes on-chip Fault Detect/Correction Circuitry, shown in a separate dotted box and connected to the two conductors that are electrically coupled to communicate with respective PAD EXTAL and PAD XTAL. As detailed in the rest of this document, Fault Detect/Correction Circuitry includes devices and connections to test various connectivity and functionality associated with oscillator 20, including both on-chip and off-chip relative to integrated circuit 200; in other words, such testing preferably includes: (1) the on-chip Other Oscillator Circuitry on integrated circuit 200; (2) the off-chip capacitors C₁ and C₂, crystal CR; and (3) the connections between those components as well as to PAD EXTAL and PAD XTAL. As part of such testing, various different types of faults may be detected and, further in a preferred embodiment, operability is included to potentially re-start the oscillation of oscillator 20 when such oscillation has been detected to have undesirably stopped. Additional details of such aspects are further explored below.

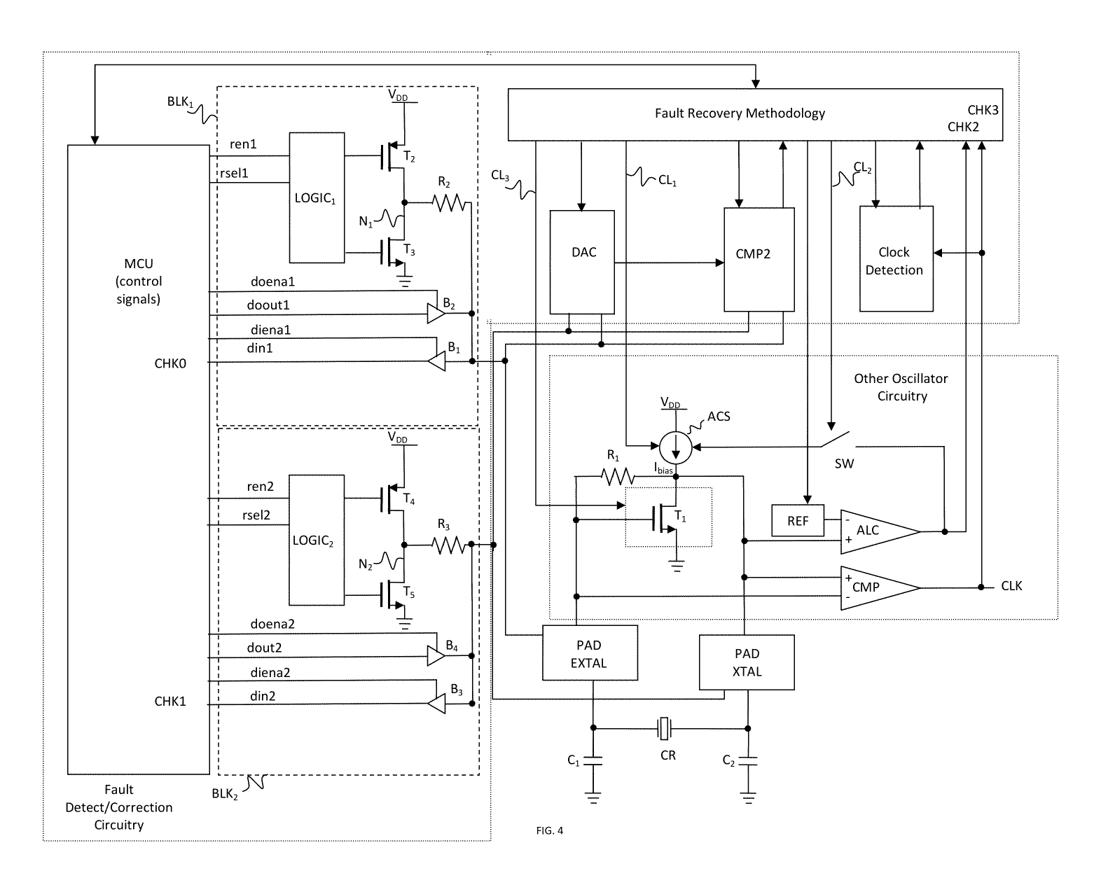

FIG. 4 illustrates a combined block diagram and schematic of oscillator 20 of FIG. 3 which, in addition to re-illustrating the oscillator off-chip components of FIG. 3, further repeats the Other Oscillator Circuitry (from FIG. 2) within a first dotted line box; further, however, FIG. 4 details the preferred embodiment Fault Detect/Correction Circuitry within a second dotted line box of integrated circuit 20, as implemented on integrated circuit 100, which may be embodied as, or may include, a microcontroller (MCU). Looking then to the Fault Detect/Correction Circuitry, it includes certain control signals that may be issued by programmability of the MCU as well as a Fault Recovery Methodology that also may be managed by MCU functionality. For reasons further evident below, therefore, the MCU/methodology can check signals shown at CHK0, CHK1, CHK2, and CHK3. In addition, Fault Detect/Correction Circuitry preferably includes a Clock Detection block, which is connected, for example, to the CLK output of oscillator 20, and may be constructed by one skilled in the art, for detecting the presence, or other analyses such as amplitude evaluation, of an oscillating signal. Such detection or analyses may be either analog, digital, or a combination thereof, for reasons and functionality further detailed later. Fault Detect/Correction Circuitry also includes a digital-to-analog converter (DAC). The DAC has a preferably 5 or 6 bit input, which may be supplied by the MCU (as either an external device or internally), and the DAC has an output connected to both PAD EXTAL and PAD XTAL. Fault Detect/Correction Circuitry also includes a comparator CMP2, having inputs connected to both PAD EXTAL and PAD XTAL and which further communicates with the Fault Recovery Methodology. Lastly, note any of the Clock Detection block, DAC, or comparator CMP2 may be ether external from the MCU or may be part of its circuitry and functionality.

Fault Recovery Methodology also includes various control and signal lines. A first line CL₁ is for control of adjustable current source ACS. A second line CL₂ is for control of a switch SW that is in the feedback control path from automatic level control ALC to adjustable current source ACS. A third line CL₃ is for control of the transconductance (e.g., effective base size) of transistor T₁; more specifically, in the preferred embodiment, the transconductance of transistor T₁ is adjustable, for example in response to a binary value so as to select from various (e.g., four) different values of transconductance. As detailed later, this adjustability may be used in conjunction with a preferred embodiment methodology for attempting to re-start oscillator 20. Looking at other signals relating to Fault Recovery Methodology, the output of automatic level control ALC is connected to Fault Recovery Methodology (for CHK2), and the output of the Other Oscillator Circuitry comparator CMP is also connected to Fault Recovery Methodology (for CHK3).

Fault Detect/Correction Circuitry also includes, in one preferred embodiment, two generally duplicated blocks BLK₁ and BLK₂, both connected to receive various control signals from MCU or other processing circuit as may be included on integrated circuit 200 of FIG. 3. The difference between block BLK₁ and block BLK₂ is that block BLK₁ is connected to PAD EXTAL, while block BLK₂ is connected to PAD XTAL. These different connections allow signal communication including either the pulling down or pulling up of, by block BLKₓ of its respective PAD, as further explored below.

Looking at block BLK₁, it includes a LOGIC₁ block having various circuitry, as may be ascertained by one skilled in the art, that is controlled for accomplishing functionality described in this document. To illustrate such control, two control signals are shown between MCU and LOGIC₁, namely: (1) ren1; and (2) rsel1. The LOGIC₁ block is connected to the gate of a p-channel transistor T₂ and to the gate of an n-channel transistor T₃. The source of p-channel transistor T₂ is connected to V_{DD}, the source of n-channel transistor T₃ is connected to ground (also sometimes referred to as V_{SS}), and the drains of n-channel transistor T₂ and p-channel transistor T₃ are connected to a node N₁, which is further connected through a resistor R₂ (e.g., 20 kOhms) to PAD EXTAL. The MCU also has a data in (din1) for the checker CHK0 and associated data in enable (diena1) and a data out (dout1) and associated data out enable (doena1). More particularly: (1) PAD EXTAL is connected as an input to a buffer B₁, which may be enabled by diena1 to provide din1 to the MCU; and (2) the MCU is connected to enable a buffer B₂ by doena1 to provide dout1 to PAD EXTAL

Looking at block BLK₂, it includes a LOGIC₂ comparable to LOGIC₁ described above, and thus has ascertainable circuitry to accommodate the above-introduced control signals, here between MCU and LOGIC₂, namely: (1) ren2; and (2) rsel2. The LOGIC₂ block is connected to the gate of a p-channel transistor T₄ and to the gate of an n-channel transistor T₅. The source of p-channel transistor T₄ is connected to V_{DD}, the source of n-channel transistor T₅ is connected to ground, and the drains of p-channel transistor T₄ and n-channel transistor T₅ are connected to a node N₂, which is further connected through a resistor R₃ to PAD XTAL. As was the case for block BLK₁, with respect to block BLK₂, the MCU also has a data in (din2) and associated data in enable (diena2) and a data out (dout2) and associated data out enable (doena2). More particularly: (1) PAD XTAL is connected as an input to a buffer B₃ which may be enabled by diena2 to provide din2 to the MCU; and (2) the MCU is connected to enable a buffer B₄ by doena2 to provide dout2 to PAD XTAL.

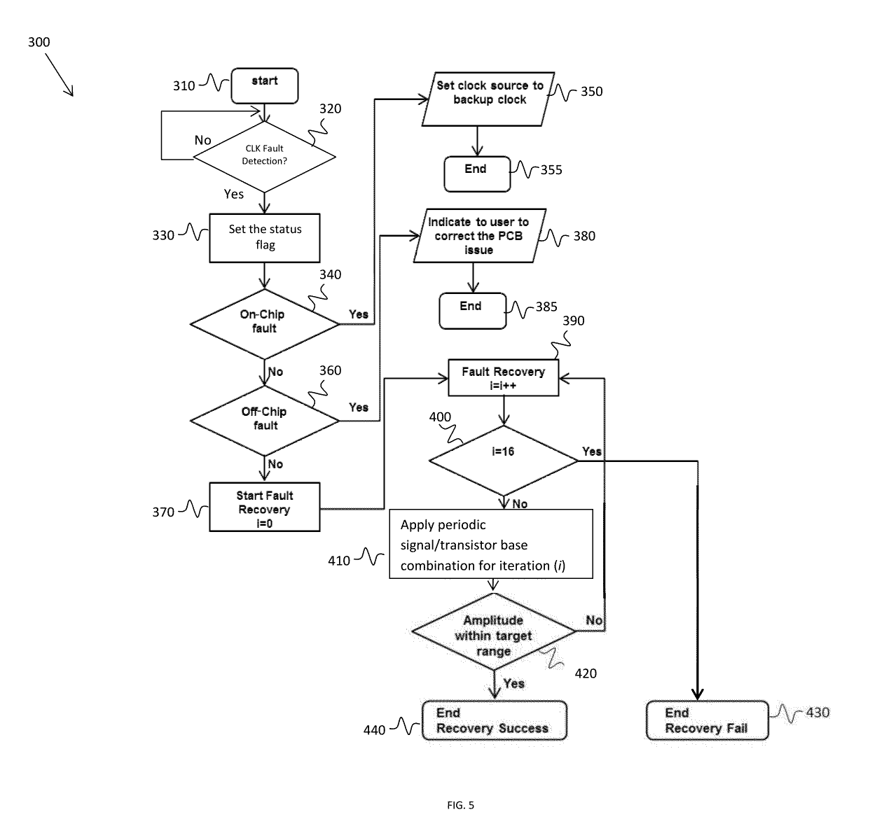

FIG. 5 illustrates a flowchart of a method 300 of operation of the FIGS. 3 and 4 Fault Detect/Correction circuitry in more detail. In general, note that the Other Oscillator Circuitry, in conjunction with PADs EXTAL and EXTAL, capacitors C₁ and C₂, and crystal CR operate as described in connection with FIGS. 1 and 2. In addition, however, the additional FIG. 5 aspects perform method 300 to monitor the oscillator oscillation and respond if a problem is detected. Such monitoring and response are now further explored, in connection with method 300.

Method 300 commences with a start step 310, followed by a looping condition 320 in which testing occurs to determine if there is an irregularity in the CLK signal, as compared to its nominally expected frequency and/or amplitude. For example, if the CLK signal is outside of expected operation, such as outside an acceptable range of frequency, if there is no oscillation (i.e., if the CLK signal is stuck for an unacceptable period of time at either a 0 or 1). More specifically, in a preferred embodiment, the step 320 testing is via either analog or digital testing, by way of example using the Clock Detection block to analyze the oscillator output CLK signal. For example, in an analog approach, the CLK signal may be applied to a capacitor (not shown) within the Clock Detection block for a predetermined period of time, and then the voltage across that capacitor is measured and compared to an expected value for nominally proper operation. As another example, in a digital approach, the number of transitions in the CLK signal (if any) are counted over a period of time, and that count is compared to an expected value for nominally proper operation. In either example, if the comparison is within an acceptable threshold, then step 320 concludes no fault is detected, and a method loop continues by returning to repeat step 320. If, however, a CLK fault is detected, method 300 continues to step 330.

Step 330 sets a status flag to represent that a fault has been detected in the oscillation output signal of oscillator 20. The flag may be accomplished by setting a logical state (or states) in various different types of electronic storage elements, such as a register in any of the Clock Detection block, LOGIC₁, LOGIC₂, the MCU, or otherwise. This flag may be checked later for purposes of additional diagnostics or the like. Next, method 300 continues from step 330 to step 340.

Step 340 determines if there is a fault related to an on-chip portion of oscillator 20. In a preferred embodiment, first this determination is achieved by block BLK₁ outputting either a pull-up or pull-down test pattern from node N₁ to PAD EXTAL, while at the same time each of checkers CHK0, CHK1, CHK2, and CHK3 are examined to determine if the binary value of each matches an expected value, indicating proper operation. If any such checker does not match the expected value, then a fault is thereby detected, according to the following Table 1:

TABLE 1

| | | | | | Switch | |
|---|---|---|---|---|---|---|
| Test pattern | CHK0 | CHK1 | CHK2 | CHK3′ | SW | Result/Fault |
| ren1 = 1, srel1 = 1 (pull- | 1 | 0 | 0 | 1 | Open | Function okay |
| up) | | | | | | |
| ren1 = 1, rsel1 = 0 | 0 | 1 | 1 | 0 | Open | Function okay |
| (pull-down) | | | | | | |
| ren1 = 1, rsel1 = 1 | 1 | 1 | 0 | 1 | Open | T₂ and I_{bias} has fault |
| (pull-up) | | | | | | |
| ren1 = 1, rsel1 = 1 | 1 | 0 | 1 | 1 | Open | CMP has function fault |
| (pull-up) | | | | | | |
| ren1 = 1, rsel1 = 1 | 1 | 0 | 0 | 0 | Open | ALC has function fault |
| (pull-up) | | | | | | |

After the heading row, the first data two rows of Table 1 illustrate respective pull-up and pull-down test patterns, and the expected binary value of each of the four checkers, while switch SW is open, thereby indicating no detected fault. In each successive row, however, an underlined value indicated a detected error, and the last column for the respective row indicates the fault. For example, in the third data row of Table 1, a value of CHK1=1 indicates a fault, with the particular fault being that T₂ and I_{bias} have a fault. The remaining examples should be apparent to one skilled in the art, given the Table and teachings of this document. Moreover, additional testing may be applied via block BLK₂, applying signals to PAD EXTAL.

Given the preceding, if step 340 determines there is an on-chip fault, method 300 continues to step 350; in step 350, in one preferred embodiment, an alternative source is established to provide the CLK signal. Such a source may be from a backup clock or the like, which preferably would be another type of oscillator, such as an relaxation oscillator or other on-chip oscillator without a crystal. Such an alternative oscillator would be provided at a lower cost and accuracy as compared to oscillator 20. Moreover, if this alternative clock source is not requested by MCU peripherals, it would be enabled only when the crystal-based oscillator 20 fails, as demonstrated in this flow chart. Thereafter, method 300 continues from step 350 to step 355, where the method ends (from where it can later return to step 310 if oscillator 20 is re-started). On the other hand, if step 340 determines there is not an on-chip fault, method 300 continues from step 340 to step 360.

Step 360 determines if there is a fault related to an off-chip portion of oscillator 20. In a preferred embodiment, the step 360 test examines one or both of whether there is a fault in a design connection in the oscillator, meaning an undesirable open circuit or closed circuit in the nominally-intended connections shown off of integrated circuit 200 in FIG. 3. For example, an open circuit could occur in the intended design to connect capacitor C₁ and the PAD EXTAL, or similarly in the intended design to connect capacitor C₂ and the PAD XTAL, or between either PAD and crystal CR. As another example, an unintended and oscillator-function-impeding closed circuit could occur between PAD EXTAL pin and PAD XTAL pin. Thus, step 360 contemplates such scenarios, as further described below.

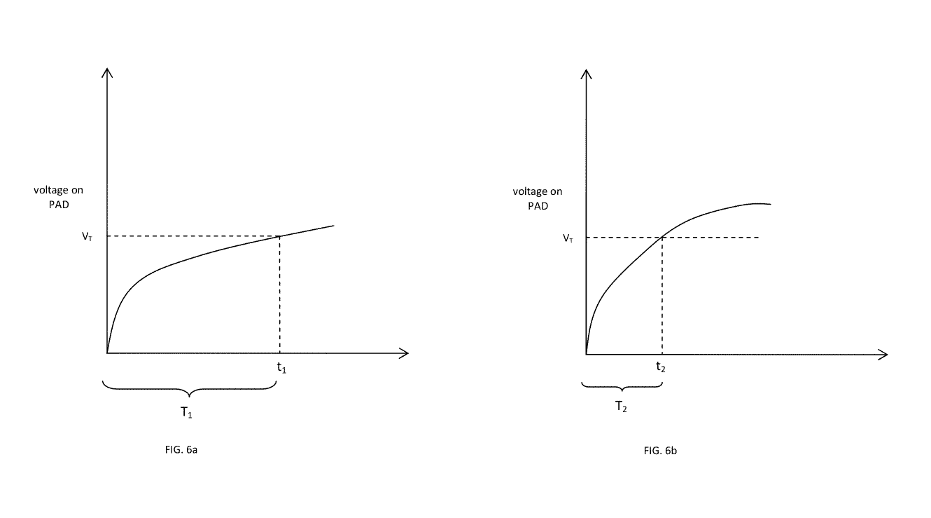

A step 360 test for an open circuit off-chip fault may be performed by a preferred embodiment as follows, as described in connection with FIG. 4 and further in view of FIGS. 6a and 6b. In general, in this test block BLK₁ applies a voltage to PAD EXTAL and the time taken for the voltage to reach a certain threshold, V_{T}, is evaluated and used to determine if PAD EXTAL is therefore properly connected to its respective capacitor C₁. More specifically, therefore, LOGIC₁ enables transistor T₂ so that current flows through resistor R₂ and the voltage at PAD EXTAL is charged up. A preferred embodiment contemplates that if capacitor C₁ is properly connected to PAD EXTAL, then an RC constant is influenced at least by resistor R₂ and capacitor C₁, with an expected voltage rising speed at for PAD EXTAL, that is, a delay for the voltage across capacitor C₁ to charge to reach a certain threshold. This expectation is shown in FIG. 6a, where an increasing voltage waveform appears at PAD EXTAL, and it reaches the threshold, V_{T}, at a time t₁. In a preferred embodiment, threshold V_{T} may be established by a digital-to-analog conversion as part of either on-chip testing (e.g., see, the DAC in FIG. 4) or by external test equipment. Moreover, the voltage at PAD EXTAL is monitored, and compared by comparator CMP2 with the threshold V_{T}. In another embodiment, this procedure can be accomplished by an external sensing circuit, and in any event the amount of time, T₁, for the waveform on PAD EXTAL is evaluated, such as via a digital count from a timer, to determine how much time passes before the event at time t₁ occurs. If the counted time to reach the t₁ event is approximately consistent with T₁ of FIG. 6a, then step 360 concludes that no open circuit exists as between PAD EXTAL and capacitor C₁. In this instance, method 300 may continue with other testing for off-chip faults, or if no such additional testing is desired or available, then method 300 continues from step 360 to step 370. FIG. 6b, however, illustrates the relative expectation if, on the other hand, an open circuit does exist between PAD EXTAL and capacitor C₁, and step 360 further tests for this instance. Particularly, in this instance, then the amount of time, T₂, to reach the t₁ event, that is, the time for the PAD EXTAL signal to reach the threshold, V_{T}, will be relatively shorter than T₁ that was shown in FIG. 6a. As a result, if the counted time to reach the t₁ event is approximately consistent with T₂ of FIG. 6b (i.e., or otherwise sufficiently less than T₁ of FIG. 6a), then step 360 concludes that an open circuit exists as between PAD EXTAL and capacitor C₁. In this case, an off chip fault has been detected, and method 300 continues from step 360 to step 380. Lastly, while the above examples describe testing for an open circuit between PAD EXTAL and capacitor C₁, a preferred embodiment further contemplates comparable testing by block BLK₂ with respect to the connection between PAD XTAL and capacitor C₂.

In step 380, having been reached due to detection of an off-chip fault, method 300 provides and/or stores an indication of the detected fault. As with step 330, such an indication may set a status flag to represent that a fault has been detected, where here more specifically the flag indicates that the fault is an off-chip fault, and further the flag may be associated with the particular error, such as specifying whether the open circuit relates to capacitor C₁ or capacitor C₂. From this indication, therefore, the flag may be polled by a user or manufacturer and the failure addressed, such as a repair made to the off-chip open circuit. Additionally or alternatively, a real-time error also may be generated that affirmatively reports to the board user the existence of the fault, without requiring the user to check the status of a flag or the like. Thereafter, method 300 continues from step 380 to step 385, where the method ends.

Returning to step 360, a test for a short circuit off-chip fault may be performed by a preferred embodiment to test one of various possibilities, including: (1) a short between PADs EXTAL and XTAL; (2) a short between PAD EXTAL and ground (e.g., via a short of capacitor C₁); and (3) a short between PAD XTAL and ground (e.g., via a short of capacitor C₂). Each of these alternatives is described below.

A step 360 test for an off-chip short circuit fault between PADs EXTAL and XTAL is shown generally in the following Table 2:

```
TABLE 2
  No fault case:
(1) Force XTAL dout2=1, EXTAL pull down. Check the EXTAL din1=0.
(2) Force XTAL dout2=0, EXTAL pull up. Check the EXTAL din1=1.
  Fault detected case:
(1) Force XTAL dout2=1, EXTAL pull down. Check the EXTAL din1=1.
(2) Force XTAL dout2=0, EXTAL pull up. Check the EXTAL din1=0.
```

As shown in the upper box of Table 2, in a first sub-step (1), a digital value of 1 is applied to PAD XTAL, such as by enabling buffer B₄ (via doena2) and providing an output value of dout2=1, and at the same time the other pad, that is, PAD EXTAL, is pulled down by LOGIC₁ enabling transistor T₃. Also in this sub-step, the value of PAD EXTAL is sampled, such as by enabling buffer B₁ and sampling the signal din1, and if the value din1=0, then the determination is that no fault is detected, as the expectation is that the pulling down of PAD EXTAL, if not shorted to PAD XTAL, will discharge PAD EXTAL to ground and cause its voltage to be 0. Note, however, that were PADs EXTAL and XTAL shorted, then the forced dout=1 at PAD XTAL will cause a non-zero voltage to appear at PAD EXTAL, that is, the sampled signal at PAD EXTAL will be din1=1, indicating a fault is detected, as shown in sub-step (1) in the lower box of Table 2. Further in the upper box of Table 2, in a second sub-step (2), a digital value of 0 is applied to PAD XTAL, again by enabling buffer B₄ (via doena2) and providing an output value of dout2=0, and at the same time the other pad, that is, PAD EXTAL, is pulled up by LOGIC₁ enabling transistor T₂. Also in this sub-step, the value of PAD EXTAL is sampled, again by enabling buffer B₁ and sampling the signal din1, and if the value din1=1, then the determination is that no fault is detected, as the expectation is that the pulling up of PAD EXTAL, if not shorted to PAD XTAL, will maintain PAD EXTAL to V_{DD} and cause its voltage to be a digital 1. Note, however, that were PADs EXTAL and XTAL shorted, then forced dout=0 at PAD XTAL will cause a zero voltage to appear at PAD EXTAL so that if the sampled signal din1=0, a fault is detected, as shown in sub-step (2) in the lower box of Table 2. Note also in this regard that some amount of time is allowed to pass after the pull-up to avoid contention between the 0 on XTAL and the 1 on EXTAL. Moreover, if there is no short, then din is determined by the resistor divider of R₁ and R₂. Specifically, considering that R₁>>R₂, for the no short case then din is near zero. Otherwise, if R₁ is shorted, then din is high.

A step 360 test for an off-chip short circuit fault between PAD XTAL and ground (i.e., V_{SS}) is shown generally in the following Table 3:

```
TABLE 3
  No fault case:
(1) Force XTAL pull up. Check the XTAL din2=1.
(2) Force XTAL pull up. Check the XTAL voltage level with 6bit DAC +
comparator for high impedance.
  Fault detected case:
(1) Force XTAL pull up. Check the XTAL din2=0.
(2) Force XTAL pull up. Check the XTAL voltage level with 6bit DAC +
comparator for high impedance.
```

The general details of pulling a PAD either up or down or data in and data out should be understood from earlier discussion, so the following more briefly reviews what one skilled in the art should understand from Table 3. As shown in the upper box of Table 3, in a first sub-step (1), PAD XTAL is pulled up and at the same time the voltage at that same PAD XTAL is sampled, from din2. If the value din2=1, then the determination is that no fault is detected, as the expectation is that the pulling up of PAD EXTAL, if not shorted to V_{SS}, will keep PAD EXTAL at V_{DD}, that is, providing din2=1. Note, however, that were PADs XTAL shorted to V_{SS}, then the pull-up voltage is discharged and din2=0, thereby indicating a detected fault, as shown in sub-step (1) of the lower box of Table 3. Further in the upper box of Table 3, in a second sub-step (2), a similar operation is performed to the first sub-step, but with an analog analysis rather than a digital one. Thus, again PAD XTAL is pulled up, but in sub-step (2) the PAD XTAL voltage is compared with a voltage from a DAC (e.g., 6 bit), such as in FIG. 4 or from an off-chip DAC. More specifically, the DAC input is increased over time so that its corresponding analog output voltage increases, and the DAC output is compared to the voltage at PAD XTAL until the comparator detects a match. The point at which the voltage matches will represent the relative impedance existing at PAD XTAL, which if relatively high is determined by step 360 to indicate the PAD is not shorted to V_{SS}, and conversely if relatively low (or at or near zero) is determined by step 360 to indicate the PAD is shorted to V_{SS}.

A step 360 test for an off-chip short circuit fault between PAD XTAL and V_{DD} is shown generally in the following Table 4:

```
TABLE 4
  No fault case:
(1) Force XTAL pull down. Check the XTAL din2=0.
(2) Force XTAL pull down. Check the XTAL voltage level with 6bit
DAC + comparator for high impedance.
  Fault detected case:
(1) Force XTAL pull down. Check the XTAL din2=1.
(2) Force XTAL pull down. Check the XTAL voltage level with 6bit
DAC + comparator for high impedance.
```

As shown in the upper box of Table 4, in a first sub-step (1), PAD XTAL is pulled down and at the same time the voltage at that same PAD XTAL is sampled, from din2. If the value din2=0, then the determination is that no fault is detected, as the expectation is that the pulling down of PAD XTAL, if not shorted to V_{DD}, will keep PAD XTAL pulled down to V_{SS}, that is, providing din2=0. Note, however, that were PAD XTAL shorted to V_{DD}, then despite the pull-down of voltage at PAD XTAL, din2=1, thereby indicating a detected fault, as shown in sub-step (1) of the lower box of Table 4. Further in the upper box of Table 4, in a second sub-step (2), a similar operation is performed to the first sub-step, but with an analog analysis rather than a digital one. Thus, again PAD XTAL is pulled down, but in sub-step (2) the PAD XTAL voltage is again compared with a voltage from a DAC, and also again the DAC input is increased over time so that its corresponding increasing output voltage may be compared to the voltage at PAD XTAL, until the comparator detects a match. The point at which the voltage matches again represents the relative impedance existing at PAD XTAL, which if relatively low is determined by step 360 to indicate the PAD is not shorted to V_{DD}, and conversely if relatively high is determined by step 360 to indicate the PAD is shorted to V_{DD}.

Returning to method 300, recall that step 320 may detect a CLK fault and continue the process toward steps 340 and 360. If, however, step 340 fails to detect an on-chip fault, and step 360 fails to detect an off-chip fault, then in a preferred embodiment method 300 continues to step 370. In general, with neither an on-chip nor off-chip failure detected, a preferred embodiment further endeavors to attempt to re-start the CLK signal to return it to its desirable oscillation frequency and amplitude, such as by way of MCU control of the DAC. For example, since no specific fault other than in the CLK signal has thus been detected, a preferred embodiment proceeds under an estimation that the oscillator may have been merely stuck in a 0 or 1 condition or subject to some influence that may have been removed or can be overcome, and additional methodology proceeds in an effort to restore nominal operation, as is shown in connection with steps 370, 390, 400, 410, 420, 430, and 440, as further explored below.

Step 370 starts a fault-recovery process, in an effort to recover the CLK signal to its normal, nominal operation (e.g., to unstick it from a value of 0 or 1). In a preferred embodiment, this process is iterative, so in this regard step 370 initializes a loop index i to a value of 0. Next, method 300 continues from step 370 to step 390.

Steps 390, 400, 410, and 420 represent the iterative looping introduced above. Thus, step 390 increments the loop counter, i, and method 300 continues from step 390 to step 400. Step 400 determines if the loop has reached a maximum iteration count, which in the example of FIG. 5 is shown as reached when i=16. If that count is reached, method 300 proceeds from step 400 to step 430, wherein it is determined that the iterative fault recovery has failed after i=16 attempts. While not shown, additional information identifying the failure may be stored and/or reported to the board user, in connection with step 430. To the contrary, if step 400 determines that the loop counter, i, has not met its maximum iteration count, method 300 continues to step 410.

In step 410, a combination of a periodic signal applied to PAD EXTAL and a transconductance selection of transistor T₁ is provided, in response to the loop index i. For example, where the loop index is first incremented to i=1, then a periodic signal having a first frequency is applied to PAD EXTAL and a first transconductance (or base size) is applied to transistor T₁. Moreover, for each incremented value of i, a respective different combination is applied, changing either the frequency or the transconductance. For example, Table 5, below, illustrates an example of a preferred embodiment list of alternative combinations of frequency/transconductance, given a respective index of i:

TABLE 5

| | | T₁ |
|---|---|---|
| | DAC | transconductance/base |
| i | frequency | size |
| 1 | f₁ | sz₁ |
| 2 | f₁ | sz₂ |
| 3 | f₁ | sz₃ |
| 4 | f₁ | sz₄ |
| 5 | f₂ | sz₁ |
| 6 | f₂ | sz₂ |
| 7 | f₂ | sz₃ |
| 8 | f₂ | sz₄ |
| 9 | f₃ | sz₁ |
| 10 | f₃ | sz₂ |
| 11 | f₃ | sz₃ |
| 12 | f₃ | sz₄ |
| 13 | f₄ | sz₁ |
| 14 | f₄ | sz₂ |
| 15 | f₄ | sz₃ |
| 16 | f₄ | sz₄ |

Table 5 should be readily understood by one skilled in the art. By way of example in comprehending Table 5, its first row illustrates the selected combination for iteration i=1, wherein the combination applies a first frequency f₁ and a first transconductance or base size sz₁ to oscillator 20. Returning briefly to FIG. 4, therefore, the selected transconductance is via control line CL₃, and the selected frequency f₁ is via the DAC. Further, in a preferred embodiment, the periodic signal may be generated by the DAC shown in FIG. 4, where for each selected frequency, the MCU applies ascending followed by descending digital values to the DAC so as to generate the periodic signal, and the numbers are provided at a speed to achieve the desired frequency for the current loop counter i. Similarly, an off-chip waveform generator also may be used to apply such a signal. The generated wave can be a sine wave, square wave or, preferably, a triangular wave. Moreover, note also that preferably the DAC is controlled so that its periodic output as an amplitude of V_{dd}/2. Next, method 300 continues from step 410 to step 420.

Step 420 is comparable to step 320 described above, that is, to determine if the CLK signal is now operating properly per nominal expectations or specifications. In other words, with step 410 having applied the periodic signal to PAD EXTAL and transconductance to transistor T₁, and with no on-chip fault (step 340) or off-chip fault (step 360) having been detected, then a preferred embodiment contemplates the applied periodic signal/base combination may excite the oscillator back into proper operation. Step 420, therefore, determines whether the output CLK signal is proper, such as by evaluating its amplitude and/or frequency. If the CLK signal is proper, method 300 continues from step 420 to step 440, in which case the oscillator operation has been successfully restored; also in this instance, therefore, the transconductance of T₁ is maintained at the new value from the iteration in which the CLK signal was restored. If, however, the CLK signal is not proper, method 300 returns from step 420 to step 390.

If step 390 is reached by return from step 420 as described above, then again step 390 increments the loop index i, followed by a check of step 400 to determine if that index has reached a maximum. If the iteration loop count is less than the step 400 maximum, step 410 will again apply a combination of periodic signal to PAD EXTAL and base size to transistor T₁, but this time at values corresponding to the new index i that has been incremented. One skilled in the art will appreciate, therefore, that the loop including steps 390 to 420 may repeat up until the maximum number of times (e.g., 16) established by step 400, wherein in each repetition a different frequency signal is applied, by a respective instance of step 410, to PAD EXTAL. Thus, a total of 16 different combinations of frequency/transconductance may be attempted, each endeavoring to excite the oscillator back into proper operation. If proper operation in reached in any of these repeated instances, then again step 420 passes control to step 440. If, however, none of the 16 instances is able to excite proper operation, then method 300 concludes with step 430, described earlier.

The specific frequency values for the four different frequencies output by the DAC (i.e., f₁ through f₄) shown in Table 5 may be selected using various alternatives. In a preferred embodiment, each of these values may be as shown in the following Table 6:

TABLE 6

| DAC | |
|---|---|
| frequency | Value |
| f₁ | Lower of: |
| | (1) original crystal frequency of crystal CR; or |
| | (2) highest frequency achievable by DAC |
| f₂ | f₁ ÷ 2 |
| f₃ | (f₁ ÷ 2) + (.02) (f₁ ÷ 2) |
| f₄ | (f₁ ÷ 2) − (.02) (f₁ ÷ 2) |

Also noted earlier is that a preferred embodiment sets the DAC amplitude at V_{dd}/2. In other embodiments, however, different amplitudes may be used. For example, if it is known that the architecture includes an automatic level control ALC as in the illustrated case of FIG. 4, then preferably the DAC amplitude is set to the voltage level provided by reference REF to the ALC. As another example, if it is know that the architecture does not include an automatic level control ALC, then preferably the DAC amplitude is set to V_{dd}.

Lastly, the preferred embodiment also may use various different sizes for the four different transistor bases sizes shown in Table 5. In a preferred embodiment, each of these values may be as shown in the following Table 7:

TABLE 7

| DAC | |
|---|---|
| frequency | Value |
| sz₁ | 0.5 times original size |
| sz₂ | 0.8 times original size |
| sz₃ | 1.2 times original size |
| sz₄ | 1.5 times original size |

From the above, various embodiments provide numerous improvements to the prior art. Such improvements include an increase in yield of properly operating oscillators, with additional functionality to test and potentially restore operation of oscillators once they are obtained by consumers. Moreover, the preferred embodiments contemplate detection of faults, either or both of on-chip and off-chip, with the storing of information that may be used by consumers and manufacturers for further improvements based on such information. Still further, the fault detection may be achieved with on-chip circuits alone, or based on a combination of on-chip and off-chip circuits, the latter including bench testing before the chip is released by the manufacturer. Still further, various aspects have been described, and still others will be ascertainable by one skilled in the art from the present teachings. Thus, while various alternatives have been provided according to the disclosed embodiments, still others are contemplated. For example, while FIG. 5 illustrates one preferred embodiment ordering of its steps, various steps may be re-arranged, eliminated, or added. As another example, while the preferred embodiment implements an iteratively changing combination of applied frequency and transistor transconductance to attempt to recover oscillator operation, in an alternative preferred embodiment either the adjustable current source ACS or the reference REF also could be adjusted. Still other examples are ascertainable by one skilled in the art. Given the preceding, therefore, one skilled in the art should further appreciate that while some embodiments have been described in detail, various substitutions, modifications or alterations can be made to the descriptions set forth above without departing from the inventive scope, as is defined by the following claims.

1. Circuitry for providing an oscillating output signal in connection with an integrated circuit chip, comprising:
a crystal, off the chip;
oscillator circuitry, on the chip, for electrically coupling with the off-chip crystal and operable to produce the oscillating output signal;
testing circuitry, on the chip, for evaluating whether the oscillating output signal is operating within an acceptable frequency range; and
operational recovery circuitry, on the chip, for attempting to restore the oscillating output signal, in response to the testing circuitry evaluating that the oscillating output signal is not operating within the acceptable frequency range.

2. The circuitry for providing an oscillating output signal of claim 1, and further comprising an output for providing the oscillating output signal, and wherein the testing circuitry comprises:
a capacitor coupled to the output; and
circuitry for comparing a voltage across the capacitor to a threshold.

3. The circuitry for providing an oscillating output signal of claim 1, wherein the testing circuitry comprises circuitry for counting a number of transitions in the oscillating output signal over a period of time.

4. The circuitry for providing an oscillating output signal of claim 1, and further comprising circuitry for storing an indicator in response to the testing circuitry evaluating that the oscillating output signal is not operating within the acceptable frequency range.

5. The circuitry for providing an oscillating output signal of claim 1, wherein the testing circuitry further comprises circuitry for determining if a fault in the oscillating output signal is responsive to a fault in the oscillator circuitry.

6. The circuitry for providing an oscillating output signal of claim 5 and further comprising a backup clock signal source for providing an alternative oscillating output signal in response to the testing circuitry detecting the fault in the oscillator circuitry.

7. The circuitry for providing an oscillating output signal of claim 1, and further comprising a first off-chip capacitor and a second off-chip capacitor, both for coupling to the oscillator circuitry for producing the oscillating output signal.

8. The circuitry for providing an oscillating output signal of claim 7, wherein the testing circuitry further comprises circuitry for determining if a fault in the oscillating output signal is responsive to a fault in at least one of the first off-chip capacitor, the second off-chip capacitor, or a design connection to one of the first off-chip capacitor or the second off-chip capacitor.

9. The circuitry for providing an oscillating output signal of claim 7, and further comprising circuitry for storing an indicator for identifying a detected failure causing the fault in the oscillating output signal.

10. The circuitry for providing an oscillating output signal of claim 1 wherein the operational recovery circuitry is for iteratively attempting to restore the oscillating output signal, in response to the testing circuitry evaluating that the oscillating output signal is not operating within the acceptable frequency range.

11. The circuitry for providing an oscillating output signal of claim 1 wherein the operational recovery circuitry is for iteratively attempting to restore the oscillating output signal, in response to the testing circuitry evaluating that the oscillating output signal is not operating within the acceptable frequency range, by applying a different frequency signal to the oscillatory circuitry for each respective iteration.

12. The circuitry for providing an oscillating output signal of claim 1 wherein the operational recovery circuitry is for iteratively attempting to restore the oscillating output signal, in response to the testing circuitry evaluating that the oscillating output signal is not operating within the acceptable frequency range, by applying a different frequency signal to an input to the oscillatory circuitry for each respective iteration.

13. The circuitry for providing an oscillating output signal of claim 1 wherein the operational recovery circuitry is for iteratively attempting to restore the oscillating output signal, in response to the testing circuitry evaluating that the oscillating output signal is not operating within the acceptable frequency range, by adjusting a transconductance of the oscillator circuitry to a different value for each respective iteration.

14. The circuitry for providing an oscillating output signal of claim 1 wherein the operational recovery circuitry is for iteratively attempting to restore the oscillating output signal, in response to the testing circuitry evaluating that the oscillating output signal is not operating within the acceptable frequency range, by providing a different combination of oscillator circuitry transconductance and applied frequency signal to the oscillatory circuitry, for each respective iteration.

15. The circuitry for providing an oscillating output signal of claim 1 wherein the operational recovery circuitry is for iteratively attempting to restore the oscillating output signal, in response to the testing circuitry evaluating that the oscillating output signal is not operating within the acceptable frequency range, by applying a different bias current to the oscillatory circuitry for each respective iteration.

16. The circuitry for providing an oscillating output signal of claim 1 and further comprising:
an input pad; and
wherein the testing circuitry comprises circuitry for applying a bias to the input pad and sampling a bias on one or more nodes in response to the bias.

17. The circuitry for providing an oscillating output signal of claim 1 and further comprising:
an output pad; and
wherein the testing circuitry comprises circuitry for applying a bias to the output pad and sampling a bias on one or more nodes in response to the bias.

18. A method of providing an oscillating output signal in connection with an integrated circuit chip, the chip comprising oscillator circuitry for electrically coupling with an off-chip crystal and operable to produce the oscillating output signal, the method comprising:
with testing circuitry on the chip, evaluating whether the oscillating output signal is operating within an acceptable frequency range; and
with operational recovery circuitry on the chip, attempting to restore the oscillating output signal, in response to the testing circuitry evaluating that the oscillating output signal is not operating within the acceptable frequency range.

19. The method of claim 18, wherein the testing circuitry is further for determining if a fault in the oscillating output signal is responsive to a fault in the oscillator circuitry.

20. The method of claim 19 and further comprising operating a backup clock signal source for providing an alternative oscillating output signal in response to the testing circuitry detecting the fault in the oscillator circuitry.

21. The method of claim 18, and further comprising a first off-chip capacitor and a second off-chip capacitor, both for coupling to the oscillator circuitry for producing the oscillating output signal.

22. The method of claim 21, wherein the testing circuitry is further for determining if a fault in the oscillating output signal is responsive to a fault in at least one of the first off-chip capacitor, the second off-chip capacitor, or a design connection to one of the first off-chip capacitor or the second off-chip capacitor.
